(19) United States
(12) Patent Application Publication
(10) Pub. No.: US 2022/0217816 A1
(43) Pub. Date: Jul. 7, 2022

(54) HEATER CONTROL UNIT

(71) Applicant: Edwards Limited, Burgess Hill (GB)

(72) Inventor: Brent Haslett, Eastbourne (GB)

(21) Appl. No.: 17/608,417

(22) PCT Filed: May 12, 2020
(86) PCT No.: PCT/GB2020/051153

§ 371 Date: Nov. 2, 2021

(30) Foreign Application Priority Data
May 14, 2019 (GB) 1906797.4

(51) Int. Cl. H05B 1/02; G05D 23/19

(52) U.S. Cl. CPC H05B 1/0247; C23C 16/4412; G05D 23/1934

(57) ABSTRACT

According to an aspect of the present disclosure there is provided a modular heater control unit. The modular heater control unit is configured to control a heating element for heating a component. The modular heater control unit includes complementary first and second ports to enable the modular heater control unit to be connected to one or more like modular heater control unit in a serial configuration. The modular heater control unit has a controller including at least one processor and at least one memory. The controller is configured to communicate with a supervisory control unit. The present disclosure also relates to a heating system; and a supervisory control unit.

This application is a national stage entry under 35 U.S.C. § 371 of International Application No. PCT/GB2020/051153, filed May 12, 2020, which claims the benefit of GB Application No. GB1906797.4, filed May 14, 2019, the entire contents of each of which are incorporated herein by reference.

### TECHNICAL FIELD

The present disclosure relates to a heater control unit. Aspects of the disclosure relate to a modular heater control unit, a modular heater unit, a heating system and a supervisory control unit.

### BACKGROUND

It is known to provide abatement systems and integrated systems with a temperature management system in order to maintain the pipework and valves at elevated temperatures. This can reduce or prevent deposition of process chemicals which may otherwise lead to blockages. The temperature management system typically comprises a plurality of heater units that are controlled by a central control unit. The heater units are connected in a chain and all of the heater units in the chain are controlled based on a temperature measured at a limited number of discrete locations by thermocouples provided on the pipework. The controller assumes that the rest of the pipework is at the same temperature since all of the heater units have the same power rating per unit area. The wiring connection associated with the temperature management system is complex. The chance of allocating the wrong thermocouple to the wrong chain may be high and, moreover, hard to detect. This has the potential to result in pipework being controlled at the wrong temperature.

It is an aim of the present disclosure to address one or more of the disadvantages associated with the prior art.

### SUMMARY

Aspects and examples of the disclosure provide a modular heater control unit, a modular heater unit, a heating system and a supervisory control unit as claimed in the appended claims.

According to an aspect of the present disclosure there is provided a modular heater control unit for controlling a heating element to heat a component, the modular heater control unit comprising: complementary first and second ports to enable the modular heater control unit to be connected to one or more like modular heater control units; and a controller comprising at least one processor and at least one memory, the controller being configured to communicate with a supervisory control unit.

The modular heater control unit can be connected to a like modular heater control unit having at least substantially the same configuration. The modular heater control units may be connected to each other in a daisy chain arrangement. The serial connection established between the modular heater control units may enable communication with the supervisory control unit. The first and second ports may, for example, comprise complementary male and female ports.

The modular heater control unit may be connected to a heating assembly. The modular heater control unit and the heating assembly may be combined to form a modular heater unit. The heating assembly may comprise or consist of a heating element. The modular heater control unit may be permanently connected to the heating assembly. Alternatively, the modular control unit may be releasably connected to the heating assembly. The modular heater control unit may comprise one or more connectors for connecting the heating assembly.

The communication with the supervisory control unit may comprise transmitting data from the controller to the supervisory control unit; and/or receiving data from the supervisory control unit.

The supervisory control unit may have a complementary port for connection to one of the first and second ports. The modular heater control unit may be connected directly or indirectly to the supervisory control unit.

In use, the modular heater control unit may be connected directly or indirectly to the supervisory control unit. By way of example, one or more like modular heater control units may be connected to each other to form a chain. The modular heater control unit may be separated from the supervisory control unit by one or more intermediary modular heater control units in the chain. The communication with the supervisory control unit may be performed via the one or more intermediary modular heater control units. One or more serial communication channels may be established along the chain formed by the modular heater control units. The at least one serial communication channel may enable communication between the supervisory control unit and the or each modular control unit in the chain.

The controller may be configured to communicate with the supervisory control unit via at least one of the first and second ports.

The first port may comprise at least one communication channel for receiving a first input signal. The first port may be connected to a like modular heater control unit. The first input signal may be received from the like modular heater control unit connected to the first port.

The first port may comprise at least one communication channel for outputting a first output signal. The first port may be connected to a like modular heater control unit. The first output signal may be output to the like modular heater control unit connected to the first port.

The second port may comprise at least one communication channel for receiving a second input signal. The second port may comprise at least one communication channel for outputting a second output signal. The second port may be connected directly or indirectly to the supervisory control unit. The second input signal may be received from the supervisory control unit. The second output signal may be output to the supervisory control unit via the second port.

The modular heater control unit may comprise a temperature sensor for measuring a temperature of the component. The controller may be configured to control the heating element in dependence on the temperature signal. The temperature sensor may be configured to output a temperature signal to the controller. The communication with the supervisory control unit may comprise transmitting the temperature signal to the supervisory control unit. The controller may be configured to receive a target temperature from the supervisory control unit.

The modular heater control unit may comprise switch means for selectively energizing the heating element. The control of the heating element may comprise controlling the switch means. The switch means may comprise a switch, for example an electromechanical switch or an electronic switch, such as a bidirectional triode thyristor.

According to a further aspect of the present disclosure there is provided a modular heater control unit for controlling a heating element, the modular heater control unit comprising: switch means for controlling the heating element; complementary first and second ports to enable like modular heater control units to be connected to each other in a daisy chain configuration; and a controller comprising at least one processor and at least one memory, the controller being configured to control operation of the switch means selectively to activate and deactivate the heating element. The switch means may be operated selectively to energize and de-energize the heating element.

The modular heater control unit may be connected to a heating assembly. The modular heater control unit and the heating assembly may be combined to form a modular heater unit. The heating assembly may comprise or consist of a heating element. The modular heater control unit may be permanently connected to the heating assembly. Alternatively, the modular control unit may be releasably connected to the heating assembly. The modular heater control unit may comprise one or more connectors for connecting the heating assembly.

The switch means may comprise a switch, for example an electromechanical switch or an electronic switch, such as a bidirectional triode thyristor.

The controller may be configured to control the heating element in dependence on the temperature signal. A target temperature may be set for the heating element. The controller may control the heating element to achieve and/or to maintain the target temperature. The modular heater control unit may be connected to a supervisory control unit. The supervisory control unit may set the target temperature.

The modular heater control unit may comprise a voltage sensor for measuring a voltage supplied to the heating element. The voltage sensor may be configured to output a voltage signal to the controller. The heater control unit may be configured to transmit the voltage signal to a supervisory control unit.

The modular heater control unit may comprise a current sensor for measuring a current supplied to the heating element. The current sensor may be configured to output a current signal to the controller. The heater control unit may be configured to transmit the current signal to the supervisory control unit.

The controller may be configured to detect faults in the modular heater control unit. The heater control unit may be configured to transmit a fault detection signal to the supervisory control unit.

According to a further aspect of the present disclosure there is provided a modular heater control unit for connection to one or more like modular heater control units, the modular heater control unit comprising: a first port for selectively connecting the heater control unit to one of a supervisory control unit and a first modular heater control unit, the first modular heater control unit having a like configuration; a second port for connecting the heater control unit to a second modular heater control unit, the second modular heater control unit having a like configuration; a controller comprising at least one processor and at least one memory, the controller being configured to communicate with the supervisory control unit or the first modular heater control unit via the first port.

The controller may be configured to communicate with the second modular heater control unit via the second port.

The modular heater control unit may be connected to a heating assembly. The modular heater control unit and the heating assembly may be combined to form a modular heater unit. The heating assembly may comprise or consist of a heating element. The modular heater control unit may be permanently connected to the heating assembly. Alternatively, the modular control unit may be releasably connected to the heating assembly. The modular heater control unit may comprise one or more connectors for connecting the heating assembly.

According to a further aspect of the present disclosure there is provided a modular heater unit comprising a modular heater control unit and at least one heating assembly. The modular heater control unit may be of the type described herein. The at least one heating assembly may of the type described herein.

According to a further aspect of the present disclosure there is provided a heating system comprising a supervisory control unit and at least a first modular heater control unit and a second modular heater control unit. The first and second modular heater control units are of the type described herein. A first heating element may be associated with the first modular heater control unit. The first modular heater control unit may control operation of the first heating element. A second heating element may be associated with the second modular heater control unit. The second modular heater control unit may control operation of the second heating element.

The supervisory control unit may be configured to set a first target temperature for the first modular heater control unit and a second target temperature for the second modular heater control unit. The first and second target temperatures may be different from each other.

According to a further aspect of the present disclosure there is provided a supervisory control unit for controlling one or more modular heater control units, the supervisory control unit comprising: a supervisory controller comprising at least one processor and at least one memory; and a port for connecting one or more modular heater control units; wherein the supervisory controller is configured to communicate with the or each modular heater control unit connected to the port. The or each modular heater control unit may be of the type described herein.

The port may comprise a communication channel for communicating with the one or more modular heater control units. The communication channel may be configured to transmit a signal to each of the one or more modular heater control units; and/or to receive a signal from each of the one or more modular heater control units.

The supervisory controller may be configured to communicate with each of a plurality of the modular heater control units connected to the port. The supervisory controller may be configured to communicate with each of the modular heater control units independently. The supervisory controller may be configured to control the modular heater control units independently of each other. The modular heater control units may be connected to each other in series to form a chain. The supervisory controller may be configured to establish serial communication with each of the modular heater control units connected to the port.

The supervisory controller may be configured to output a control signal to each of the modular heater control units. By way of example, the supervisory controller may be configured to output a target temperature signal for each of the modular heater control units. The supervisory controller may be configured to receive a signal from each of the modular heater control units. By way of example, the supervisory controller may be configured to receive a temperature signal or a fault signal from each of the modular heater control units.

The supervisory controller may be configured to identify each modular heater control unit connected to the port. The supervisory controller may be configured to establish communication with each of the modular heater control units connected to the port in a chain. The supervisory controller may be configured to identify each modular heater control unit in a chain composed of a plurality of the modular heater control units. The supervisory controller may output an independent control signal to each of the one or more identified modular heater control unit.

It is to be understood that the or each controller described herein can comprise a control unit or computational device having one or more electronic processors (e.g., a microprocessor, a microcontroller, an application specific integrated circuit (ASIC), a complex programmable logic device (CPLD), a field-programmable gate array (FPGA), etc.), and may comprise a single control unit or computational device, or alternatively different functions of the or each controller may be embodied in, or hosted in, different control units or computational devices. As used herein, the term “controller,” “control unit,” or “computational device” will be understood to include a single controller, control unit, or computational device, and a plurality of controllers, control units, or computational devices collectively operating to provide the required control functionality. A set of instructions could be provided which, when executed, cause the controller to implement the control techniques described herein (including some or all of the functionality required for the method described herein). The set of instructions could be embedded in said one or more electronic processors of the controller; or alternatively, the set of instructions could be provided as software to be executed in the controller. A first controller or control unit may be implemented in software run on one or more processors. One or more other controllers or control units may be implemented in software run on one or more processors, optionally the same one or more processors as the first controller or control unit. Other arrangements are also useful.

Within the scope of this application it is expressly intended that the various aspects, embodiments, examples and alternatives set out in the preceding paragraphs, in the claims and/or in the following description and drawings, and in particular the individual features thereof, may be taken independently or in any combination. That is, all embodiments examples and/or features of any embodiment example can be combined in any way and/or combination, unless such features are incompatible. The applicant reserves the right to change any originally filed claim or file any new claim accordingly, including the right to amend any originally filed claim to depend from and/or incorporate any feature of any other claim although not originally claimed in that manner.

### BRIEF DESCRIPTION OF DRAWINGS

One or more examples of the disclosure will now be described, by way of example only, with reference to the accompanying drawings.

FIG. 1 shows a schematic representation of a heating system incorporating a modular heater control unit in accordance with an example of the present disclosure.

FIG. 2 shows a schematic representation of the modular heater control unit shown in FIG. 1.

FIG. 3 shows a schematic representation of a control unit for the modular heater control unit shown in FIG. 2.

### DETAILED DESCRIPTION

A heating system 1 comprising a plurality of modular heater units MH-n in accordance with an example of the present disclosure is described herein with reference to the accompanying Figures.

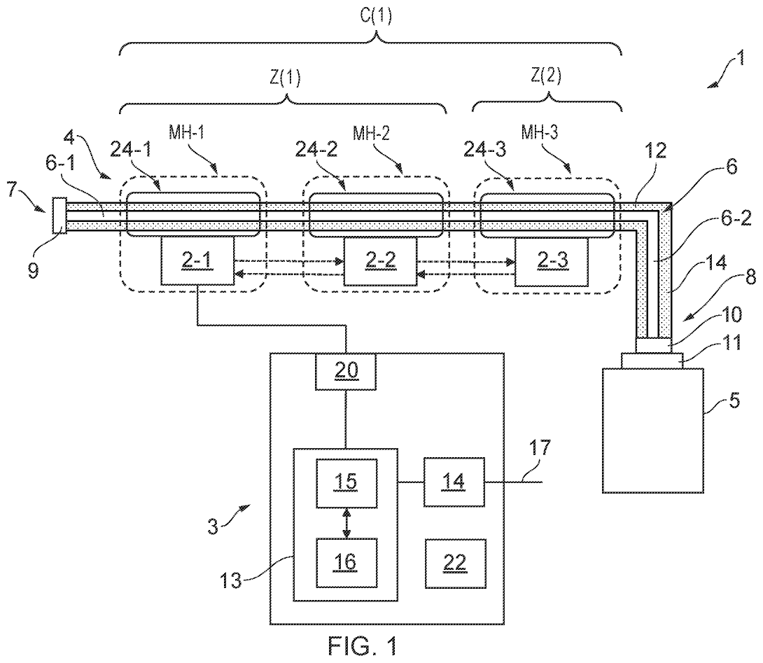

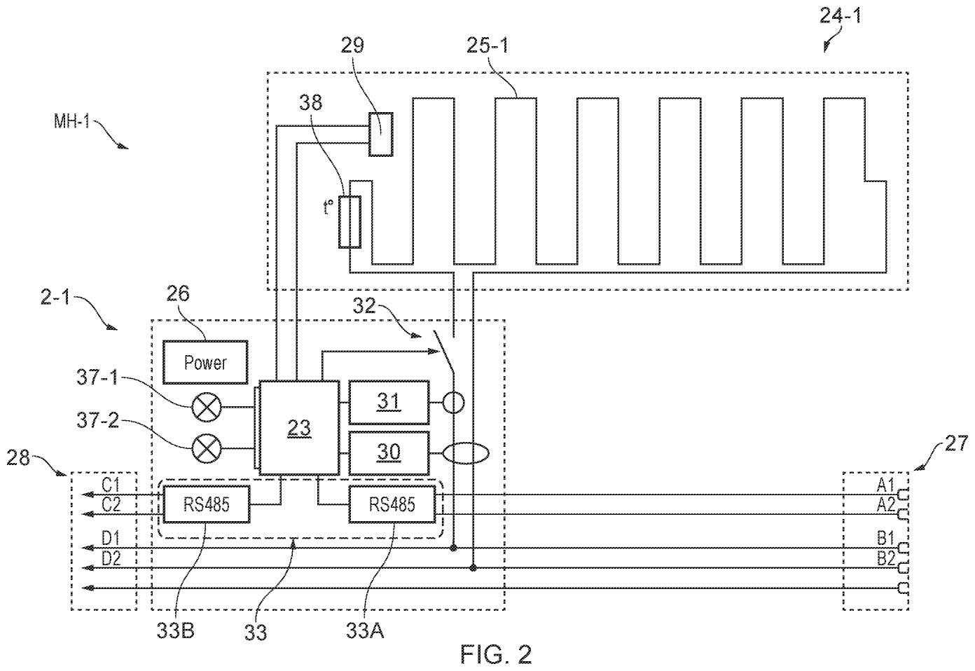

As shown in FIG. 1, the heating system 1 in the present example comprises first, second and third modular heater units MH-1, MH-2, MH-3. It will be appreciated that the heating system 1 may comprise less than or more than three (3) modular heater units MH-n. The modular heater units MH-n each comprise a modular heater control unit 2-n and a heater assembly 24-n. The modular heater control units 2-n are individual units which are connected to each other in series to form a daisy chain arrangement. The heater assemblies 24-n each comprise at least one heating element 25 (shown in FIG. 2). Each heater assembly 24-n is controlled by one of the modular heater control units 2-n. In use, the modular heater control units 2-n are configured to provide independent control of each of the heater assemblies 24-n.

The heating system 1 comprises a supervisory control unit 3 for controlling operation of the modular heater units MH-n. A master-slave relationship is established between the supervisory control unit 3 and each of the modular heater control units 2-n. The supervisory control unit 3 operates as a master device for controlling each of the slave modular heater units MH-n. The supervisory control unit 3 can control the modular heater units MH-n collectively, for example to set a common heating rate for the modular heater units MH-n, and/or a common target temperature for the modular heater units MH-n. The supervisory control unit 3 can also control the modular heater units MH-n independently of each other, for example to set discrete heating rates for each of the modular heater units MH-n, and/or a discrete target temperature for each of the modular heater units MH-n.

The heating system 1 is operative to control the temperature of an exhaust system 4 for conveying process gases to an abatement device 5. The exhaust system 4 may, for example, be provided to transport deposition gases and associated powders expelled from a chemical vapour deposition (CVD) process. The heating system 1 is configured to control the temperature of the exhaust system 4 to ensure that compounds remain volatile, thereby preventing or suppressing the accumulation of solids which may partially or completely block the exhaust system 4. It will be understood that the heating system 1 can be used in other industrial processes.

As shown in FIG. 1, the exhaust system 4 comprises a conduit 6. The conduit 6 is in the form of a tube composed of a metal, such as stainless steel. The conduit 6 may, for example, comprise a DN40 pipe having an internal diameter of 40 mm and a length of 10 metres or more. The conduit 6 may follow a convoluted path. The conduit 6 forms a substantially continuous fluid path for conveying exhaust gases to the abatement device 5. The conduit 6 could consist of a single length of pipe. However, the conduit 6 typically comprises a plurality of subsections 6-1, 6-2 joined together in a fluid-tight manner. The conduit 6 may comprise one or more bends to provide the required connection to the abatement device 5. The exhaust system 4 has an inlet 7 and an outlet 8. An inlet coupling 9 is provided at the inlet 7; and an outlet coupling 10 is provided at the outlet 8. The outlet coupling 10 connects the exhaust system 4 to the abatement device 5. The inlet and outlet couplings 9, 10 each comprise an O-ring for forming a fluid-tight seal with the associated components. Other types of seal may be employed to form the fluid-tight seal. A valve 11 is provided at the outlet 8 of the exhaust system 4. In certain examples, the valve 11 may be omitted. The valve 11 is operable selectively to open and close the outlet 8. A lagging 12 is provided around an exterior of the conduit 6 to provide thermal insulation.

The supervisory control unit 3 comprises a supervisory controller 13 and a power module 14. The supervisory controller 13 comprises at least one first processor 15 and a system memory 16. A set of computational instructions is stored in the system memory 16. When executed, the computational instructions cause the first processor 15 to perform the method(s) described herein. The power module 14 has an electrical input 17 for connection to a mains electricity supply RMS or other electrical power source. The supervisory control unit 3 comprises at least one base port 20. In the present example, the base port 20 is in the form of a socket. The or each base port 20 is adapted to be connected to one of the modular heater control units 2-n. The modular heater control unit 2-n connected to the base port 20 can be connected in series to one or more additional modular heater control units 2-n. Each base port 20 can support a separate chain C(n) composed of one or more of the modular heater units MH-n. By providing a plurality of base ports 20, the supervisory control unit 3 can be configured to support more than one such chain C(n). Each chain C(n) of the modular heater units MH-n may be arranged to provide temperature control of a separate component or a separate zone Z(n). A human machine interface (HMI) 22 is provided for controlling operation of the supervisory control unit 3. The HMI 22 in the present example is implemented on a touch screen (not shown) connected to the supervisory control unit 3. In a variant, the supervisory control unit 3 can be connected to a general-purpose computational device, such as a personal computer.

As shown in FIG. 1, the first, second and third modular heater units MH-1, MH-2, MH-3 comprise respective first, second and third modular heater control units 2-1, 2-2, 2-3. The first, second and third modular heater control units 2-1, 2-2, 2-3 are connected to each other in a daisy-chain arrangement. The first modular heater control unit 2-1 is connected to the supervisory control unit 3; the second modular heater control unit 2-2 is connected to the first modular heater control unit 2-1; and the third modular heater control unit 2-3 is connected to the second modular heater control unit 2-2. The first, second and third modular heater control units 2-1, 2-2, 2-3 all have at least substantially the same configuration. For the sake of brevity, the first modular heater control unit 2-1 will now be described in detail. It will be understood that the second and third modular heater control units 2-2, 2-3 have at least substantially the same configuration as the first modular heater control unit 2-1.

A schematic representation of the first modular heater unit MH-1 is shown in FIG. 2. The first modular heater unit MH-1 comprises a first modular heater control unit 2-1 and a first heater assembly 24-1. The first modular heater control unit 2-1 comprises a first module controller 23. The first heater assembly 24-1 comprises a first heating element 25-1. The first heater assembly 24-1 may be permanently connected to the first module controller 23. Alternatively, the first heater assembly 24-1 may be removably connected to the first module controller 23, for example to facilitate servicing or maintenance. The first modular heater control unit 2-1 comprises an on-board power supply 26, a first (slave) port 27, a second (master) port 28, a first temperature sensor 29, a voltage sensor 30, a current sensor 31, a control switch 32 and a communication unit 33. The first port 27 and the second port 28 are complementary to enable like modular heater control units 2-n to be connected to each other. The first temperature sensor 29 could optionally be incorporated into the first heater assembly 24-1. The first heater assembly 24-1 may comprise one or more fasteners (nor shown), for example a hook and loop fastener, to retain the first heating element 25-1 in position. The first heater assembly 24-1 may optionally comprise a thermally-insulating element, for example in the form of a pad or layer. The thermally-insulating element may be disposed on an outer surface of the first heating element 25-1 to reduce heat loss. It will be understood that the thermally-insulating element may be omitted. A separate thermally-insulating element may be applied after the first heating element 25-1 is installed.

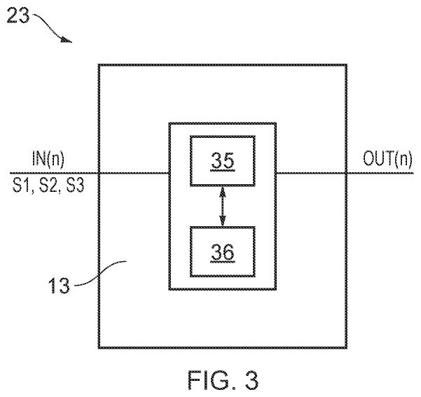

The first heating element 25-1 in the present example is a resistive heater and electrical current is passed through the first heating element 25-1 to generate heat. The first heating element 25-1 may, for example, comprise a nichrome wire. Other types of first heating element 25-1 can be used. As shown in FIG. 3, the module controller 23 comprises at least one second processor 35 and a second memory 36. The second processor 35 comprises a plurality of electrical inputs IN-n and a plurality of electrical outputs OUT-n. A set of computational instructions is stored in the second memory 36. When executed, the computational instructions cause the second processor 35 to perform the method(s) described herein. The on-board power supply 26 provides a power source for the module controller 23. The on-board power supply 26 may be connected to a mains power supply, for example from the heater supply. Alternatively, the first port 27 and the second port 28 may comprise a separate power line for supplying power to the first module controller 23. In a further variant, the on-board power supply 26 may comprise a battery. The first modular heater control unit 2-1 in the present example comprises at least one status indicator 37-n for indicating an operational status. The or each status indicator 37-n may, for example, comprise a light emitting diode (LED). In the present example, the first modular heater control unit 2-1 comprises first and second indicators 37-1, 37-2. The first indicator 37-1 comprises a red LED which is activated to indicate a fault condition. The second indicator 37-2 comprises a green LED which is activated to indicate a normal condition. It will be understood that the at least one status indicator 37-n may be omitted.

The first temperature sensor 29 is configured to measure a temperature of a section of the conduit 6 being heated by the first modular heater control unit 2-1. The first temperature sensor 29 in the present example is disposed on an interior of the first heater assembly 24-1 and configured to contact the exterior surface of the conduit 6. The first temperature sensor 29 outputs a temperature signal S1 to the module controller 23. The temperature signal S1 is transmitted to a first input IN-1 of the second processor 35. The voltage sensor 30 is configured to measure a voltage of the electrical supply to the first heating element 25-1. The voltage sensor 30 outputs a voltage signal S2 to the module controller 23. The voltage signal S2 is transmitted to a second input IN-2 of the second processor 35. The current sensor 31 is configured to measure a current of the electrical supply to the first heating element 25-1. The current sensor 31 outputs a current signal S3 to the module controller 23. The current signal S3 is transmitted to a third input IN-2 of the second processor 35. A second temperature sensor 38 may be provided to monitor the temperature of the first heating element 25-1. The second temperature sensor 38 may provide a fail-safe function, for example to detect if the temperature of the first heating element 25-1 is greater than a predefined threshold. Alternatively, or in addition, a thermal cut-out may be provided to prevent the first heating element 25-1 exceeding a thermal limit. The thermal cut-out may be self-resetting. The second temperature sensor 38 and/or the thermal cut-out may be incorporated into the first heater assembly 24-1 or the first heating element 25-1.

The communication unit 33 is configured to transmit and receive data. The communication unit 33 in the present example implements the RS-485 standard for serial communication, although other communication protocols or methods could be employed. The communication unit 33 is illustrated as comprising a first transceiver 33A for downstream communication (for example with the next modular heater control unit 2-1 in the chain C(n)); and a second transceiver 33B for upstream communication (for example with the supervisory control unit 3 or with one or more other modular heater control units 2-1). It will be understood that the first and second transceivers 33A, 33B could be combined. The communication unit 33 could be incorporated into the module controller 23.

The first and second ports 27, 28 are complementary to enable like modular heater control units 2-n to be connected to each other in series. The first and second ports 27, 28 may, for example, be complementary male and female ports. The base port 20 provided on the supervisory control unit 3 also has the same configuration as the first port 27 to enable connection of one of the modular heater control units 2-n. It will be understood that any one of the modular heater control units 2-n can be connected to the base port 20 or to another one of the modular heater control unit 2-n. The composition of the first and second ports 27, 28 will now be described in more detail. The first port 27 is in the form of a socket; and the second port 28 is in the form of a plug. It will be understood that the configuration of the first and second ports 27, 28 may be reversed.

The first port 27 is configured to connect the first modular heater control unit 2-1 to another like modular heater control unit 2-n. In the illustrated arrangement, the first port 27 connects the first modular heater control unit 2-1 to the second modular heater control unit 2-2. The first port 27 comprises a plurality of electrical connectors for establishing a wired connection with the second modular heater control unit 2-2. The first port 27 comprises two (2) first communication channels A1, A2 for transmitting and/or receiving data. The first communication channels A1, A2 are connected to the first transceiver 33A for communication with the second modular heater control unit 2-2. The first port 27 comprises two (2) first power connectors B1, B2 for supplying power to the next modular heater control unit 2-n in the chain C(n). The second port 28 is configured to connect the first modular heater control unit 2-1 to the base port 20 of the supervisory control unit 3 (or to the first port 27 of another modular heater control unit 2-n). The second port 28 comprises a plurality of electrical connectors for establishing a wired connection with the supervisory control unit 3. The second port 28 comprises two (2) second communication channels C1, C2 for transmitting and/or receiving data. The second communication channels C1, C2 are connected to the second transceiver 33B for communication with the supervisory control unit 3. The second port 28 comprises two (2) second power connectors D1, D2 for supplying electricity from the power module 14 to the first heating element 25-1. A persistent electrical connection is maintained between the first power connectors B1, B2 and the second power connectors D1, D2. This arrangement forms a pass-through circuit to ensure that there is a persistent power connector between each of the first, second and third modular heater units MH-1, MH-2, MH-3 in the chain C(n) and the power module 14, regardless of the operating state of any one of the modular heater control units 2-n.

As described herein, the modular heater control units 2-n have complementary first and second ports 27, 28 to enable like modular heater control units 2-n to be connected to each other in a daisy chain arrangement. Furthermore, the supervisory control unit 3 comprises a complementary base port 20 for connection with the second port 28 of one of the modular heater control units 2-n. In use, the modular heater control units 2-n can be connected to each other or to the supervisory control unit 3. The supervisory control unit 3 can communicate with each of the modular heater control units 2-n. For example, the supervisory control unit 3 can transmit and receive data over the serial connection established between the modular heater control units 2-n.

Each of the modular heater control units 2-n comprises a module controller 23. The module controller 23 enables independent control of the heating elements 24, for example if a plurality of the modular heater control units 2-n are connected together. The module controllers 23 may also be configured to detect faults on the associated modular heater unit MH-n. The communication module 33 can transmit a fault notification to the supervisory control unit 3. The fault notification may, for example, identify one or more of the following: the affected modular heater unit MH-n; a fault condition; and a part number of the faulty component. The module controller 23 can control operation of the one or more status indicators 37-n to indicate a current (i.e. instantaneous) operating status of the modular heater unit MH-n. The module controller 23 monitors the temperature of the conduit 6 in dependence on the temperature signal S1 received from the first temperature sensor 29. The module controller 23 is capable of controlling the first heating element 25-1 in dependence on the temperature signal S1, for example to achieve and maintain a target temperature. The target temperature may, for example, be set by the supervisory control unit 3. The module controller 23 can also monitor the voltage and the current supplied to the first heating element 25-1 in dependence on the voltage signal S2 and the current signal S3. The module controller 23 may be configured to determine one or more operating parameters of the associated modular heater unit MH-n. For example, the operating time (run hours); an operating temperature; and/or the operating time at different temperatures may be determined. These operating parameters may enable predictive maintenance of the modular heater units for example when the operating time exceeds a predefined service level; or a temperature threshold is exceeded.

The supervisory control unit 3 can identify each of the modular heater control units 2-n connected in a chain C(n). The supervisory control unit 3 can also identify the sequence of each of the modular heater control units 2-n in the chain C(n). For example, the supervisory control unit 3 can determine the sequence in which the first, second and third modular heater control units 2-1, 2-2, 2-3 are connected in the chain C(n). The supervisory control unit 3 may thereby identify each of the modular heater units MH-n and optionally also a sequence of the modular heater units MH-n. At least in certain embodiments examples, the sequence can be determined without the need to set network addresses for each modular heater control unit 2-n, thereby reducing installation time and the possibility of errors occurring during installation.

The modular heater control units 2-n each have a communication module 33 for communicating with the supervisory control unit 3. In use, one or more operating parameters of each modular heater control unit 2-n can be transmitted to the supervisory control unit 3. The modular heater control units 2-n may each transmit a measured temperature of the conduit 6 to the supervisory control unit 3. This enables separate sections 6-n of the conduit 6 to be monitored and may facilitate identification of localised problems. The supervisory control unit 3 may identify drift in a duty-cycle of one or more of the modular heater control units 2-n, for example indicating that a section of the conduit 6 is blocked. The supervisory control unit 3 can check the temperature of each modular heater unit to confirm the temperature throughout the heating system 1. This may enable identification of problems with the installation (for example, a missing thermal insulation) can be detected and reported. The minimum temperature of each section could be recorded, for example to generate a guide as to possible causes of future blockages in the conduit 6.

The modular heater units are connected together in a serial arrangement to form a chain C(n) for heating the conduit 6. In the arrangement illustrated in FIG. 1, first, second and third modular heater units MH-1, MH-2, MH-3 are connected to each other to form a first chain C(1). The supervisory control unit 3 can control one or more of the first, second and third modular heater units MH-1, MH-2, MH-3 within the first chain C(1). The supervisory control unit 3 can implement the same control strategy for each of the first, second and third modular heater units MH-1, MG-2, MH-3. For example, the supervisory control unit 3 could set a universal heating rate; and/or set a universal target temperature. The supervisory control unit 3 can also implement independent control of the first, second and third modular heater units MH-1, MH-2, MH-3. For example, the supervisory control unit 3 could set a plurality of heating rates; and/or set a plurality of target temperatures. The ability to control the first, second and third modular heater units MH-1, MH-3 independently offers additional control strategies. For example, the supervisory control unit 3 can sequence activation of the first, second and third modular heater units MH-1, MH-2, MH-3. By activating the first, second and third modular heater units M-1, MH-2, MH-3 at different times (for example in a staggered sequence) the power load can be smoothed, potentially reducing a peak demand.

The supervisory control unit 3 may optionally implement a soft-start sequence so that the modular heater units achieve an operating temperature as quickly as possible. The soft-start may be initiated as part of a power-on operation or following a power outage. The soft-start sequence could, for example, activate one or more modular heater units MH-n associated with cooler sections of the conduit 6 to perform heating before other sections of the conduit 6 are heated.

The modular heater units MH-n may each be allocated to a particular zone Z(n). By way of example, a first zone Z(1) and a second zone Z(2) are shown in FIG. 1. The zones Z(n) may each comprise one or more of the modular heater units MH-n. A different target temperature may be specified for different zones Z(n), or for different sub-sections of the same zone Z(n). The modular heater units MH-n in each zone Z(n) may be controlled to heat the conduit 6 to the specified target temperature. A maximum power may be specified for each zone and the modular heater units MH-n in that zone Z(n) can be controlled to raise the temperature of that zone as quickly as possible, but without exceeding a maximum configured power level. At least in certain examples, this can be achieved whilst providing a controllable limit and a smoothed power demand. It may be possible to raise the temperature of a localised region of the conduit 6 to try and ‘burn off’ any residue build-up.

The modular heater control units 2-n may transmit a signal indicating the current and voltage supplied to the respective heating elements 24. The supervisory control unit 3 may determine a power load of each modular heater unit A total power load for a zone Z(n) or section of the conduit 6 can be determined. This may, for example, enable a check to be made that all phases of a 3-phase supply are equally balanced. At least in certain examples, a check can be performed to ensure that the modular heater units MH-n in each zone have been installed as expected and have all been connected. The supervisory control unit 3 can check the power drawn by each of the modular heater units MH-n. This may facilitate identification of technical issues, for example in relation to thermal insulation. Any such technical issues identified by the supervisory control unit 3 can be reported using an appropriate reporting strategy.

It will be appreciated that various changes and modifications can be made to the present disclosure without departing from the scope of the present application.

The modular heater control units 2-n described herein could be configured to operate at a ‘universal voltage’, either by having a power capability that is higher than typical operating requirements or by including dual heating elements 24. This would ensure that the modular heater units MH-n could control the actual achieved temperature, irrespective of the rating of a particular first heating element 25-1. This may reduce or avoid the need for multiple parts for different operating voltages, or may remove the need for voltage reducing transformers when used on high voltage installations.

1. A modular heater control unit for controlling a heating element to heat a component, the modular heater control unit comprising:
complementary first and second ports configured to enable the modular heater control unit to be connected to one or more like modular heater control unit in a serial configuration to form a chain;
a controller comprising at least one processor and at least one memory, the controller being configured to communicate with a supervisory control unit; and
a communication unit configured to transmit and receive data, the communication unit comprising:
a first transceiver connected to the first port for downstream communication with the a next modular heater control unit in the chain; and
a second transceiver connected to the second port for upstream communication with the supervisory control unit or the next modular heater control unit in the chain.

2. The modular heater control unit as claimed in claim 1, wherein the controller is configured to communicate with the supervisory control unit via at least one of the first and or second ports.

3. The modular heater control unit as claimed in claim 1, wherein the first port comprises at least one communication channel connected to the first transceiver for receiving a first input signal.

4. The modular heater control unit as claimed claim 1, wherein the first port comprises at least one communication channel connected to the second transceiver for outputting a first output signal.

5. The modular heater control unit as claimed in claim 1, wherein the second port comprises at least one communication channel connected to the second transceiver for receiving a second input signal and at least one communication channel connected to the second transceiver for outputting a second output signal.

6. The modular heater control unit as claimed in claim 1, further comprising a temperature sensor configured to measure a temperature of the component; the temperature sensor being further configured to output a temperature signal to the controller, wherein communication with the supervisory control unit comprises transmitting the temperature signal to the supervisory control unit and wherein the controller is configured to control the heating element in dependence on the temperature signal.

7. The modular heater control unit (2-n) as claimed in claim 6, further comprising switch means configured to selectively energize the heating element; wherein the controller is configured to control the heating element by at least controlling the switch means.

8. The modular heater control unit (2-n) as claimed in claim 1, further comprising switch means configured to control the heating element (25-n), wherein the controller is configured to control operation of the switch means selectively to activate and deactivate the heating element.

9. The modular heater control unit as claimed in claim 1, wherein the first port comprises two (2) first power connectors configured to supply power to the next modular heater control unit in the chain; and the second port comprises two (2) second power connectors configured to supply electricity to the heating element; wherein a persistent electrical connection is maintained between the first power connectors and the second power connectors.

10. The modular heater control unit as claimed in claim 9, further comprising a voltage sensor configured to measure a voltage supplied to the heating element; the voltage sensor being configured to output a voltage signal to the controller, wherein the controller is configured to transmit the voltage signal to the supervisory control unit.

11. The modular heater control unit as claimed in claim 9, further comprising a current sensor configured to measure a current supplied to the heating element; the current sensor being configured to output a current signal to the controller, wherein the controller is configured to transmit the current signal to the supervisory control unit.

12. The modular heater control unit as claimed in claim 1, wherein the controller is configured to detect faults in the modular heater control unit; wherein the communication with the supervisory control unit comprises transmitting a fault detection signal to the supervisory control unit.

13. A modular heater unit comprising:
a modular heater control unit as claimed in claim 1; and
at least one heating assembly.

14. A heating system comprising:
a supervisory control unit and at least a first modular heater control unit and a second modular heater control unit, the first and second modular heater control units being of the type claimed in claim 1, wherein the supervisory control unit is configured to set a first target temperature for the first modular heater control unit and a second target temperature for the second modular heater control unit, the first and second target temperatures being different from each other.

15. A supervisory control unit for controlling one or more modular heater control units as set forth in claim 1, the supervisory control unit comprising:
a supervisory controller comprising at least one processor and at least one memory; and
a port configured to connect a plurality of the modular heater control units connected to each other in series to form a chain;
wherein the supervisory controller is configured to communicate with each modular heater control unit connected to the port to identify each of the modular heater control units in the chain and to identify the sequence of the modular heater control units in the chain.

16. The supervisory control unit as claimed in claim 15, wherein the supervisory controller is configured to:
communicate with each of the-plurality of the modular heater control units connected to the port; and
establish communication with each of the modular heater control units connected to the port in the chain.
